(19) United States
(12) Patent Application Publication
(10) Pub. No.: US 2026/0121588 A1
(43) Pub. Date: Apr. 30, 2026

(54) SEMICONDUCTOR MODULE

(71) Applicant: Murata Manufacturing Co., Ltd., Nagaokakyo-shi (JP)

(72) Inventor: Yuusuke SATOU, Nagaokakyo-shi (JP)

(73) Assignee: Murata Manufacturing Co., Ltd., Nagaokakyo-shi (JP)

(21) Appl. No.: 19/433,225

(22) Filed: Dec. 26, 2025

Related U.S. Application Data
(63) Continuation of application No. PCT/JP2024/021321, filed on Jun. 12, 2024.

(30) Foreign Application Priority Data
Jun. 30, 2023 (JP) 2023-108696

(51) Int. Cl. H03F 1/26; H03F 1/56; H03F 3/24

(52) U.S. Cl. CPC H03F 1/26; H03F 1/565; H03F 3/245; H03F 2200/267; H03F 2200/451

(57) ABSTRACT

A semiconductor module includes a semiconductor device having a power terminal, a power supply path connected to the power terminal, and a first and second inductors in the power supply path. A capacitor has a first end connected to the power supply path and a second end connected to a ground. The second inductor is disposed in the power supply path, and connected between the first inductor and the power terminal. The first inductor and the second inductor are arranged to couple a magnetic field generated at the first inductor and a magnetic field generated at the second inductor.

### CROSS-REFERENCE TO RELATED APPLICATIONS

This application is a continuation of International Application No. PCT/JP2024/021321, filed Jun. 12, 2024, which claims priority to Japanese Patent Application No. 2023-108696, filed Jun. 30, 2023, the entire contents of each of which are hereby incorporated by reference.

### TECHNICAL FIELD

The present disclosure generally relates to a semiconductor module, and more specifically relates to a semiconductor module including a semiconductor device and a capacitor.

### BACKGROUND ART

Patent Document 1 discloses a power amplifier (semiconductor module) including an amplifier (semiconductor device), an inductor, and a bypass capacitor (capacitor).

In the power amplifier disclosed in Patent Document 1, the inductor is connected between the amplifier and a bias power supply (direct-current power supply). The bypass capacitor is connected between the ground and a contact between the inductor and the bias power supply.

### CITATION LIST

### Patent Document

Patent Document 1: International Publication No. 2011/092910

### SUMMARY

The present disclosure is directed to providing a semiconductor module capable of reducing high-frequency noises.

A semiconductor module according to an aspect of the present disclosure includes a semiconductor device, a power supply path, a first inductor, a capacitor, and a second inductor. The semiconductor device includes a power terminal. The power supply path is connected to the power terminal in the semiconductor device. The first inductor is disposed in the power supply path. The capacitor has a first end and a second end. In the capacitor, the first end is connected to the power supply path, and the second end is connected to a ground. The second inductor is disposed in the power supply path, and connected between the first inductor and the power terminal. The first inductor and the second inductor are disposed to couple a magnetic field generated at the first inductor and a magnetic field generated at the second inductor.

### BRIEF DESCRIPTION OF DRAWINGS

FIG. 1 is a schematic diagram of a semiconductor module according to a first embodiment.

FIG. 2A is a perspective view of a related portion of the semiconductor module according to the first embodiment. FIG. 2B is a partially broken cross-sectional view of the semiconductor module according to the first embodiment.

FIG. 3A is a diagram illustrating a mutual inductance generated at the semiconductor module according to the first embodiment. FIG. 3B is an equivalent circuit diagram of a related portion of the semiconductor module according to the first embodiment.

FIG. 4 is a circuit diagram of the semiconductor module according to the first embodiment.

FIG. 5A a plan view of a related portion of a semiconductor module according to a first modification example of the first embodiment. FIG. 5B is a cross-sectional view of the semiconductor module according to the first modification example, taken along line X1-X1 in FIG. 5A.

FIG. 6 is a schematic diagram of a semiconductor module according to a second embodiment.

FIG. 7A is a perspective view of a related portion of the semiconductor module according to the second embodiment. FIG. 7B is a partially broken cross-sectional view of the semiconductor module according to the second embodiment.

FIG. 8 is a diagram illustrating a mutual inductance generated at the semiconductor module according to the second embodiment.

FIG. 9 is a circuit diagram of the semiconductor module according to the second embodiment.

FIG. 10 is a schematic diagram of a semiconductor module according to a modification example of the second embodiment.

### DESCRIPTION OF EMBODIMENTS

Hereafter, for example, first and second embodiments are described with reference to the drawings. The drawings referred to in the description of, for example, the first and second embodiments below are schematic. The size and the thickness of components in the drawings do not necessarily reflect the actual dimensions, and the ratios in size and thickness between the components do not necessarily reflect the ratios of the actual dimensions.

The inventor recognized that, in the power amplifier disclosed in Patent Document 1, the performance of the bypass capacitor may deteriorate due to an equivalent series inductance (ESL) of the bypass capacitor, and high-frequency noise may leak to the amplifier.

The semiconductor module as described in detail below with respect to various embodiments is capable of reducing high-frequency noises. As used herein, the terms “high-frequency” and “high-frequency noise” generally refer to frequencies exceeding the audio range, including but not limited to Radio Frequencies (RF) and microwave frequencies (e.g., from several MHz to several tens of GHz) typically utilized in wireless communication standards.

### First Embodiment

A semiconductor module 100 according to a first embodiment is described with reference to the drawings.

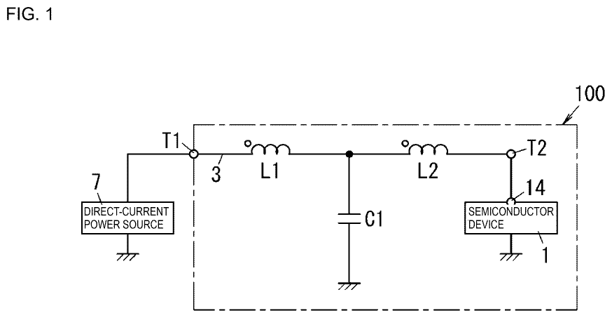

As illustrated in FIG. 1, the semiconductor module 100 according to the first embodiment is connected to a direct-current power supply 7, and the power supply voltage of the direct-current power supply 7 is provided to the power terminal of a semiconductor device 1.

The semiconductor module 100 is used as, for example, a communication device. An example of the communication device is a mobile phone (for example, a smartphone), but may be, for example, a wearable terminal (for example, a smartwatch) instead of a mobile phone.

### (1) CIRCUIT CONFIGURATION OF SEMICONDUCTOR MODULE

Hereafter, the circuit configuration of the semiconductor module 100 according to the first embodiment is described with reference to the drawings.

As illustrated in FIG. 1, the semiconductor module 100 includes a first terminal T1, a second terminal T2, a ground terminal, a semiconductor device 1, a power supply path 3, a first inductor L1, a capacitor C1, and a second inductor L2. The semiconductor device 1 includes a power terminal 14. The power supply path 3 is connected to the power terminal 14 in the semiconductor device 1 and may include conductive traces, via conductors, and/or conductive planes disposed within or on the module substrate. The first inductor L1 is disposed in the power supply path 3 and is electrically connected in series with the power supply path 3. The capacitor C1 has a first end and a second end. In the capacitor C1, the first end is connected to the power supply path 3, and the second end is connected to the ground terminal (e.g., a ground reference provided by a ground layer of the module substrate 5). The second inductor L2 is disposed in the power supply path 3 and is electrically connected in series with the power supply path 3, and connected between the first inductor L1 and the power terminal 14.

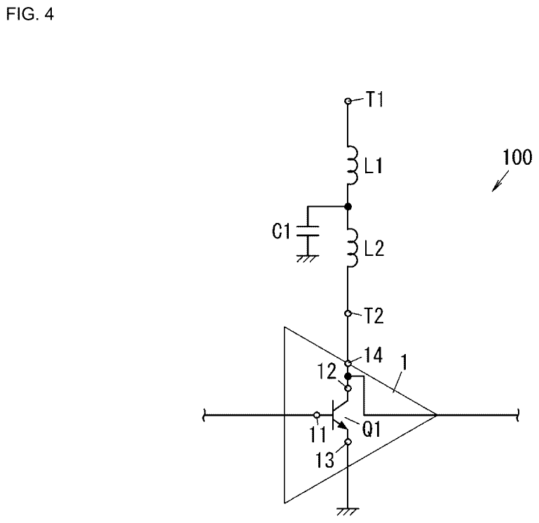

The semiconductor device 1 is, for example, a power amplifier that power-amplifies a radio signal, and includes a transistor Q1 that power-amplifies a radio signal, as illustrated in FIG. 4. The transistor Q1 is a npn bipolar transistor. The transistor Q1 includes an input terminal 11, an output terminal 12, and a grounding terminal 13. In the transistor Q1, the input terminal 11, the output terminal 12, and the grounding terminal 13 respectively function as a base terminal, a collector terminal, and an emitter terminal. The input terminal 11 in the transistor Q1 is a terminal into which a radio signal is input. The grounding terminal 13 in the transistor Q1 is a terminal connected to the ground terminal. The output terminal 12 in the transistor Q1 is connected to the direct-current power supply 7 through the power terminal 14, the second terminal T2, the second inductor L2, the first inductor L1, and the first terminal T1. A power supply voltage is applied from the direct-current power supply 7 to the transistor Q1 (across the output terminal 12 and the grounding terminal 13 in the transistor Q1). The transistor Q1 amplifies a radio signal input into the input terminal 11, and outputs the radio signal from the output terminal 12. A bipolar transistor that forms the transistor Q1 is, for example, a heterojunction bipolar transistor (HBT).

The input terminal 11 in the transistor Q1 is connected to a signal processing circuit of the communication device through a signal input terminal. The output terminal 12 of the transistor Q1 is connected to an antenna of the communication device through an antenna terminal. The power amplifier amplifies a radio signal of a predetermined band output from the signal processing circuit and outputs the radio signal.

Each of the first inductor L1 and the second inductor L2 has a first end and a second end. The first end of the first inductor L1 is connected to the first terminal T1. The second end of the first inductor L1 is connected to the first end of the second inductor L2. The second end of the second inductor L2 is connected to the second terminal T2. The second terminal T2 is connected to the power terminal 14 in the semiconductor device 1. The first inductor L1 and the second inductor L2 function as choke coils that reduce high-frequency noises directing from the direct-current power supply 7 toward the power terminal 14 in the semiconductor device 1.

The capacitor C1 is connected to the second end of the first inductor L1 and the first end of the second inductor L2. The capacitor C1 functions as, for example, a bypass capacitor that reduces leakage of high-frequency noise generated at the semiconductor device 1 to the direct-current power supply 7.

### (2) STRUCTURE AND EQUIVALENT CIRCUIT OF SEMICONDUCTOR MODULE

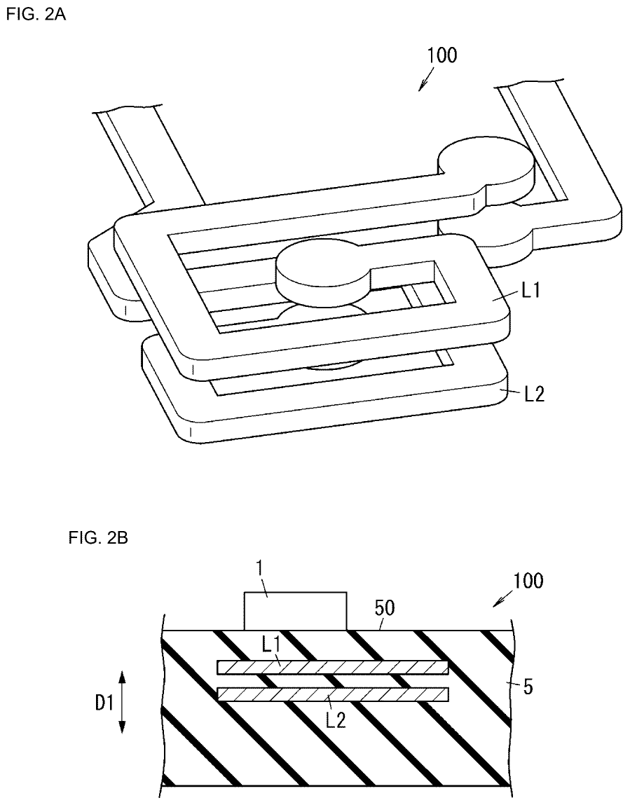

As illustrated in FIG. 2B, the semiconductor module 100 includes a module substrate 5. The module substrate 5 has a main surface 50.

When viewed in plan in a thickness direction D1 (refer to FIG. 2B) of the module substrate 5, an outer edge of the module substrate 5 is, for example, rectangular, but may have a shape other than a rectangular shape. The module substrate 5 is, for example, a multilayer substrate including multiple dielectric layers and multiple electroconductive layers. The electroconductive layers are formed from, for example, copper. The multiple electroconductive layers include a ground layer.

The module substrate 5 is, for example, a low temperature co-fired ceramic (LTCC) substrate. Instead of an LTCC substrate, the module substrate 5 may be formed from, for example, a printed circuit board, a high temperature co-fired ceramic (HTCC) board, a resin multilayer substrate, or a component-embedded board.

The semiconductor device 1 is a semiconductor chip. The semiconductor chip is a GaAs chip, but may be an Si chip instead of a GaAs chip. The semiconductor device 1 may be disposed in the module substrate 5 or mounted on a surface of module substrate 5. More specifically, the semiconductor device 1 may be disposed in the main surface 50 of the module substrate 5. The expression that “the semiconductor device 1 is disposed in the module substrate 5” includes a case where the semiconductor device 1 is mechanically connected to the module substrate 5 and a case where the semiconductor device 1 is electrically connected to the module substrate 5.

The capacitor C1 is a chip capacitor. The capacitor C1 is disposed in the module substrate 5. More specifically, the capacitor C1 is disposed in the main surface 50 of the module substrate 5. The expression that “the capacitor C1 is disposed in the module substrate 5” indicates that the capacitor C1 is mechanically connected to the module substrate 5, and that the capacitor C1 is electrically connected to the module substrate 5.

As illustrated in FIG. 2A and FIG. 2B, the first inductor L1 and the second inductor L2 are inner-layer inductors disposed in the module substrate 5.

The first inductor L1 includes a wire portion wound in a spiral form when viewed in plan in the thickness direction D1 of the module substrate 5. The second inductor L2 includes a wire portion wound in a spiral form when viewed in plan in the thickness direction D1 of the module substrate 5.

As illustrated in FIG. 2A and FIG. 2B, in the semiconductor module 100, the first inductor L1 and the second inductor L2 are disposed to couple a magnetic field generated at the first inductor L1 and a magnetic field generated at the second inductor L2, i.e., the inductors are magnetically coupled. The first inductor L1 and the second inductor L2 are disposed to be coupled to each other.

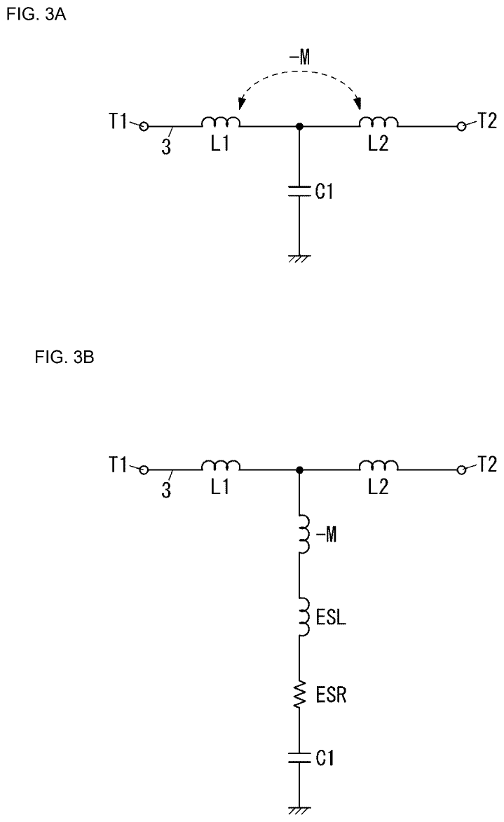

In the semiconductor module 100, the winding direction of the first inductor L1 and the winding direction of the second inductor L2 are opposite to each other, and a part of the first inductor L1 and a part of the second inductor L2 overlap in the thickness direction D1 of the module substrate 5. In the semiconductor module 100, the first inductor L1 and the second inductor L2 are adjacent to each other in the thickness direction D1 of the module substrate 5. The expression that the first inductor L1 and the second inductor L2 are adjacent to each other indicates that the first inductor L1 and the second inductor L2 are disposed without having any other circuit element disposed therebetween. The second end of the first inductor L1 and the first end of the second inductor L2 are connected in the module substrate 5 through a via conductor. In the semiconductor module 100, the first inductor L1 and the second inductor L2 are negatively coupled, and a negative mutual inductance is indicated as “−M” in FIG. 3A. FIG. 3B is an equivalent circuit expressing negative coupling between the first inductor L1 and the second inductor L2, and a negative inductance “−M” with respect to the ground is generated at the path between the first inductor L1 and the second inductor L2. The first inductor L1 and second inductor L2 are arranged such that a current flowing through the power supply path creates magnetic fluxes in the inductors that oppose each other (destructive interference), thereby generating a negative mutual inductance.

The equivalent circuit in FIG. 3B illustrates, in addition to the first inductor L1, the second inductor L2, and the capacitor C1, a negative mutual inductance as a circuit element (inductor). The equivalent circuit in FIG. 3B also illustrates an equivalent series resistance (ESR) and an equivalent series inductance (ESL) in the capacitor C1.

In the semiconductor module 100, a negative inductance cancels out the ESL in the capacitor C1, and thus allows the capacitor C1 to behave as an approximately ideal capacitor.

### (3) EFFECTS

The semiconductor module 100 according to the first embodiment includes the first inductor L1 and the second inductor L2 disposed in the power supply path 3, and the capacitor C1 connected between the power supply path 3 and the ground, and the first inductor L1 and the second inductor L2 are disposed to couple a magnetic field generated at the first inductor L1 and a magnetic field generated at the second inductor L2. The semiconductor module 100 according to the first embodiment can thus reduce high-frequency noises. The semiconductor module 100 according to the first embodiment can thus reduce high-frequency noises that leak from the direct-current power supply 7 toward the power terminal 14 in the semiconductor device 1.

### (4) MODIFICATION EXAMPLE

### (4.1) First Modification Example

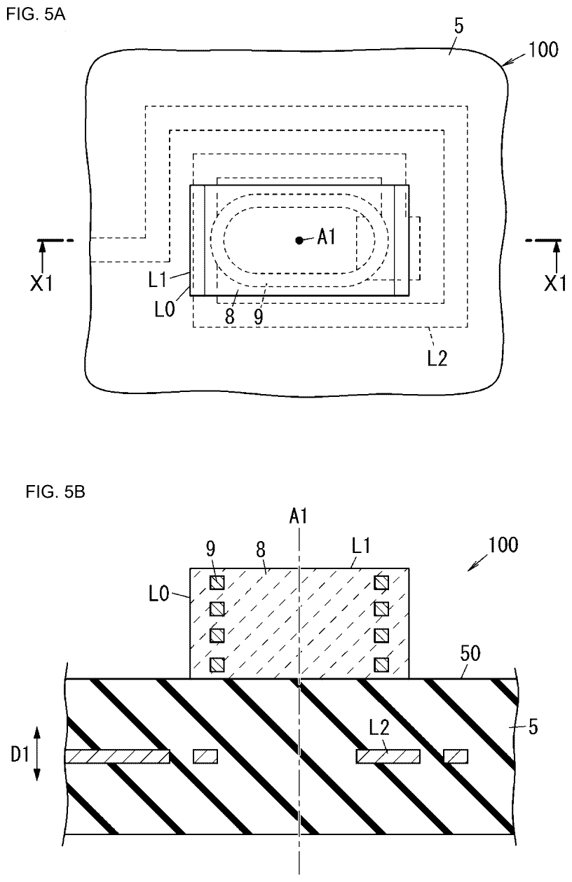

As illustrated in FIGS. 5A and 5B, a semiconductor module 100 according to a first modification example of the first embodiment differs from the semiconductor module 100 according to the first embodiment in that a first inductor L1 is formed from a chip inductor L0. Components the same as those in the semiconductor module 100 according to the first embodiment are denoted by the same reference signs without being described.

When viewed in plan in the thickness direction D1 of the module substrate 5, the outer edge of the chip inductor L0 is rectangular.

The chip inductor L0 includes a wound portion 9, a rectangular parallelepiped element 8 that covers the wound portion 9, and a pair of outer electrodes. The wound portion 9 is disposed in the element 8. The wound portion 9 is connected between the pair of outer electrodes. The wound portion 9 is a coil conductor and has electroconductivity. The wound portion 9 has, for example, a spiral shape. The element 8 is formed from a material containing any of ceramics. The pair of outer electrodes are formed from a material such as Cu or Ag. The wound portion 9 is formed from a material containing, for example, the same material as the pair of outer electrodes, but the material is not limited to this. The chip inductor L0 is a longitudinally wound inductor, and is disposed in the main surface 50 of the module substrate 5 while allowing a winding axis A1 (refer to FIG. 5B) of the wound portion 9 to be parallel to the thickness direction D1 of the module substrate 5.

In the semiconductor module 100 according to the first modification example, the first inductor L1 is the chip inductor L0, and the second inductor L2 is a spiral-shaped inner-layer inductor disposed in the module substrate 5. The winding axis A1 of the wound portion 9 in the chip inductor L0 is parallel to the thickness direction D1 of the module substrate 5.

In the semiconductor module 100 according to the first modification example, the first inductor L1 and the second inductor L2 overlap when viewed in plan in the thickness direction D1 of the module substrate 5. In the example illustrated in FIG. 5A and FIG. 5B, a part of the first inductor L1 and a part of the second inductor L2 overlap. Alternatively, the entirety of the first inductor L1 may overlap the entirety of the second inductor L2, or a part of the first inductor L1 may overlap the entirety of the second inductor L2.

### (4.2) Second Modification Example

In a semiconductor module 100 according to a second modification example, the first inductor L1 is a spiral-shaped inner-layer inductor disposed in the module substrate 5, and the second inductor L2 is a chip inductor disposed in the module substrate 5.

The semiconductor module 100 according to each of the first and second modification examples of the first embodiment has the same effects as the semiconductor module 100 according to the first embodiment.

### Second Embodiment

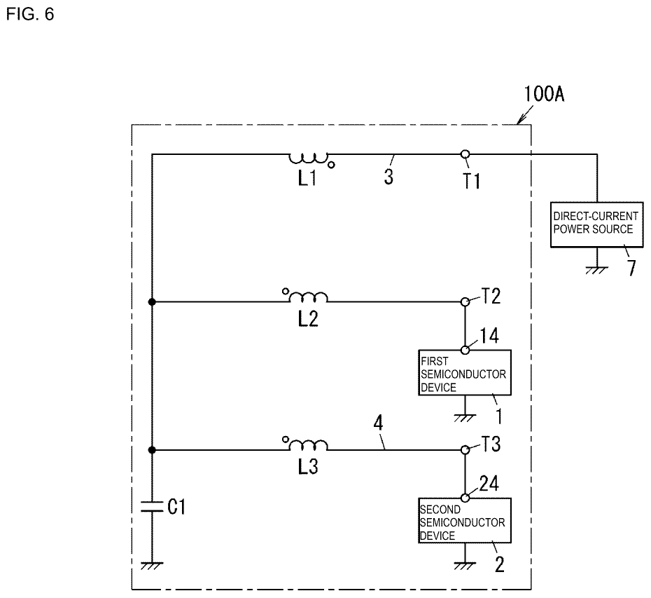

A semiconductor module 100A according to a second embodiment is described with reference to FIG. 6 to FIG. 9. Components in the semiconductor module 100A according to the second embodiment the same as those in the semiconductor module 100 according to the first embodiment (refer to FIG. 1 to FIG. 4) are denoted by the same reference signs without being described.

### (1) CIRCUIT CONFIGURATION OF SEMICONDUCTOR MODULE

Hereafter, a circuit configuration of the semiconductor module 100A according to the second embodiment is described with reference to the drawings.

As illustrated in FIG. 6, as in the case of the semiconductor module 100 according to the first embodiment, the semiconductor module 100A includes a first terminal T1, a second terminal T2, a ground terminal, a semiconductor device 1 (hereafter also referred to as a first semiconductor device 1), a power supply path 3 (hereafter also referred to as a first power supply path 3), a first inductor L1, a capacitor C1 (first capacitor C1), and a second inductor L2. The semiconductor module 100A further includes a third terminal T3, a second semiconductor device 2, a second power supply path 4, a third inductor L3, a first matching circuit MN1 (refer to FIG. 9), a second matching circuit MN2 (refer to FIG. 9), and a second capacitor C2 (refer to FIG. 9). The second semiconductor device 2 includes a power terminal 24. The second power supply path 4 is connected between a contact (also referred to herein as a connection node) between the first inductor L1 and the second inductor L2 at the first power supply path 3 and the power terminal 24 in the second semiconductor device 2. The third inductor L3 is disposed in the second power supply path 4. The third inductor L3 is connected to the power terminal 24 in the second semiconductor device 2 through the third terminal T3.

As illustrated in FIG. 9, the first semiconductor device 1 includes, for example, a transistor Q1 (hereafter also referred to as a first transistor Q1) that power-amplifies a radio signal. The second semiconductor device 2 includes, for example, a second transistor Q2 that power-amplifies a radio signal. Each of the first transistor Q1 and the second transistor Q2 is a npn bipolar transistor. The first transistor Q1 includes an input terminal 11 (hereafter also referred to as a first input terminal 11), an output terminal 12 (hereafter also referred to as a first output terminal 12), and a grounding terminal 13 (hereafter also referred to as a first grounding terminal 13). In the first transistor Q1, the first input terminal 11, the first output terminal 12, and the first grounding terminal 13 respectively function as a base terminal, a collector terminal, and an emitter terminal. The second transistor Q2 includes an input terminal 21 (hereafter also referred to as a second input terminal 21), an output terminal 22 (hereafter also referred to as a second output terminal 22), and a grounding terminal 23 (hereafter also referred to as a second grounding terminal 23). In the second transistor Q2, the second input terminal 21, the second output terminal 22, and the second grounding terminal 23 respectively function as a base terminal, a collector terminal, and an emitter terminal. The second output terminal 22 in the second semiconductor device 2 is connected to the direct-current power supply 7 through the power terminal 24, the third terminal T3, the third inductor L3, the first inductor L1, and the first terminal T1. A power supply voltage is applied from the direct-current power supply 7 to the second transistor Q2 (across the second output terminal 22 and the second grounding terminal 23 in the second transistor Q2). Bipolar transistors that form the first transistor Q1 and the second transistor Q2 are, for example, HBTs.

The first matching circuit MN1 is connected to the first input terminal 11 in the first transistor Q1 in the first semiconductor device 1. The second matching circuit MN2 is connected between the first output terminal 12 in the first transistor Q1 in the first semiconductor device 1 and the second input terminal 21 in the second transistor Q2 in the second semiconductor device 2.

The first input terminal 11 in the first transistor Q1 is connected to the signal processing circuit of the communication device through the first matching circuit MN1 and the signal input terminal. The second output terminal 22 in the second transistor Q2 is connected to the antenna of the communication device through a filter or an antenna terminal.

The third inductor L3 has a first end and a second end. The first end of the third inductor L3 is connected to the second end of the first inductor L1 and the first end of the second inductor L2. The second end of the third inductor L3 is connected to the third terminal T3. The third terminal T3 is connected to the power terminal 24 in the second semiconductor device 2. The first inductor L1 and the second inductor L2 function as choke coils that reduce high-frequency noises directing from the direct-current power supply 7 toward the power terminal 14 in the first semiconductor device 1. The first inductor L1 and the third inductor L3 function as choke coils that reduce high-frequency noises directing from the direct-current power supply 7 toward the power terminal 24 in the second semiconductor device 2.

### (2) STRUCTURE AND EQUIVALENT CIRCUIT OF SEMICONDUCTOR MODULE

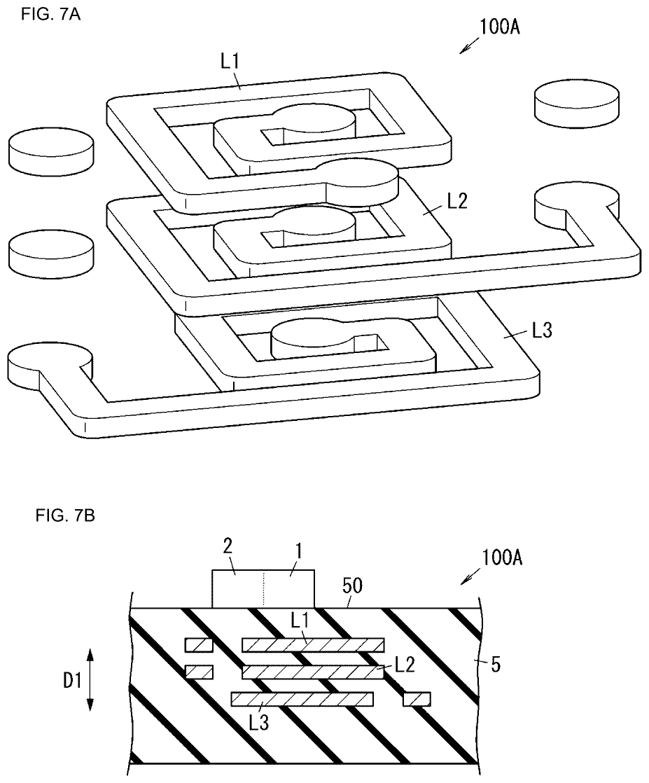

As illustrated in FIG. 7B, the semiconductor module 100A includes a module substrate 5. The module substrate 5 has a main surface 50.

The first semiconductor device 1 and the second semiconductor device 2 are disposed in the module substrate 5. More specifically, the first semiconductor device 1 and the second semiconductor device 2 are disposed in the main surface 50 of the module substrate 5. More specifically, an integrated circuit (IC) chip including the first semiconductor device 1 and the second semiconductor device 2 is disposed in the main surface 50 of the module substrate 5.

The capacitor C1 is a chip capacitor. The capacitor C1 is disposed in the module substrate 5.

As illustrated in FIG. 7A and FIG. 7B, the first inductor L1, the second inductor L2, and the third inductor L3 are inner-layer inductors disposed in the module substrate 5.

When viewed in plan in the thickness direction D1 of the module substrate 5, the first inductor L1 is spiral-shaped. When viewed in plan in the thickness direction D1 of the module substrate 5, the second inductor L2 is spiral-shaped. When viewed in plan in the thickness direction D1 of the module substrate 5, the third inductor L3 is spiral-shaped.

In the semiconductor module 100A, the first inductor L1 and the second inductor L2 are disposed to couple a magnetic field generated at the first inductor L1 and a magnetic field generated at the second inductor L2, and the second inductor L2 and the third inductor L3 are disposed to couple a magnetic field generated at the second inductor L2 and a magnetic field generated at the third inductor L3. In the semiconductor module 100A, the first inductor L1 and the third inductor are disposed to be negatively coupled to generate a negative mutual inductance.

In the semiconductor module 100A, the first inductor L1, the second inductor L2, and the third inductor L3 are arranged in this order in the thickness direction D1 of the module substrate 5 from the main surface 50 of the module substrate 5.

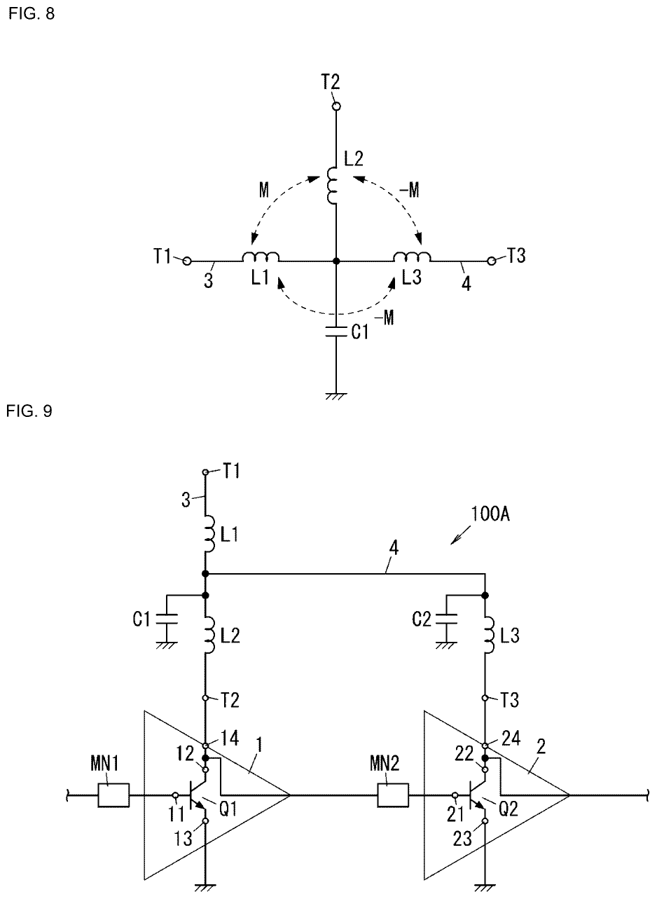

In the semiconductor module 100A, the winding direction of the first inductor L1 and the winding direction of the second inductor L2 are the same, and a part of the first inductor L1 and a part of the second inductor L2 overlap in the thickness direction D1 of the module substrate 5. In the semiconductor module 100A, the first inductor L1 and the second inductor L2 are adjacent to each other in the thickness direction D1 of the module substrate 5. The second end of the first inductor L1 and the first end of the second inductor L2 are connected in the module substrate 5 through a first via conductor. In the semiconductor module 100A, the first inductor L1 and the second inductor L2 are positively coupled, and a positive mutual inductance with respect to the ground is generated at the path between the first inductor L1 and the second inductor L2. In FIG. 8, the positive mutual inductance is indicated as “M”.

In the semiconductor module 100A, the winding direction of the second inductor L2 and the winding direction of the third inductor L3 are opposite, and a part of the second inductor L2 and a part of the third inductor L3 overlap in the thickness direction D1 of the module substrate 5. In the semiconductor module 100A, the second inductor L2 and the third inductor L3 are adjacent to each other in the thickness direction D1 of the module substrate 5. The first end of the second inductor L2 and the first end of the third inductor L3 are connected in the module substrate 5 through the second via conductor. In the semiconductor module 100A, the second inductor L2 and the third inductor L3 are negatively coupled, and a negative mutual inductance with respect to the ground is generated at a path between the second inductor L2 and the third inductor L3. In FIG. 8, the negative mutual inductance is indicated as “−M”.

In the semiconductor module 100A according to the second embodiment, the first inductor L1 and the third inductor L3 are not adjacent to each other in the thickness direction D1 of the module substrate 5.

### (3) EFFECTS

The semiconductor module 100A according to the second embodiment includes a second power supply path 4 connected between the power terminal 24 in the second semiconductor device 2 and a contact between the first inductor L1 and the second inductor L2 at the first power supply path 3, and a third inductor L3 disposed in the second power supply path 4. The semiconductor module 100A can thus reduce high-frequency noises leaking from the second power supply path 4 to the second semiconductor device 2.

The semiconductor module 100A according to the second embodiment can ensure isolation between the first power supply path 3 and the second power supply path 4. More specifically, the semiconductor module 100A according to the second embodiment can ensure isolation between a path between the first terminal T1 and the second terminal T2 and a path between the third terminal T3 and the first terminal T1.

### (4) MODIFICATION EXAMPLE

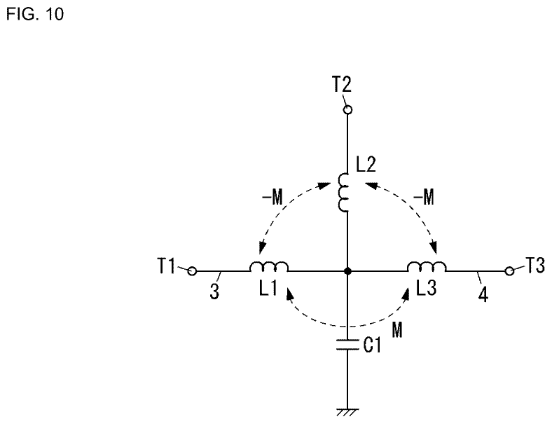

In a semiconductor module 100A according to a modification example of the second embodiment, as illustrated in FIG. 10, the first inductor L1 and the second inductor L2 may be negatively coupled, the second inductor L2 and the third inductor L3 may be negatively coupled, and the first inductor L1 and the third inductor L3 may be positively coupled. In this case, the winding direction of the first inductor L1 and the winding direction of the second inductor L2 are opposite, the winding directions of the second inductor L2 and the third inductor L3 are opposite, and the winding direction of the first inductor L1 and the winding direction of the third inductor L3 are the same.

The semiconductor module 100A according to the modification example of the second embodiment has the same effects as the semiconductor module 100A according to the second embodiment.

The first and second embodiments and other embodiments are mere examples in various embodiments of the present invention.

The first and second embodiments and other embodiments may be modified in various manners in accordance with, for example, design changes, as long as they can achieve the objective of the present invention.

Each of the first transistor Q1 included in the first semiconductor device 1 and the second transistor Q2 included in the second semiconductor device 2 may be, for example, a field effect transistor (FET), including metal oxide semiconductor FET (MOSFET), instead of a bipolar transistor.

Each of the first semiconductor device 1 and the second semiconductor device 2 may be any semiconductor device that is operated by a power supply voltage supplied from the direct-current power supply 7, and may be, for example, a low noise amplifier or a switch instead of a power amplifier.

### (Aspects)

The aspects of the present application are described as below.

A semiconductor module (100, 100A) according to a first aspect includes a semiconductor device (1), a power supply path (3), a first inductor (L1), a capacitor (C1), and a second inductor (L2). The semiconductor device (1) includes a power terminal (14). The power supply path (3) is connected to the power terminal (14) in the semiconductor device (1). The first inductor (L1) is disposed in the power supply path (3). The capacitor (C1) has a first end and a second end. In the capacitor (C1), the first end is connected to the power supply path (3), and the second end is connected to a ground. The second inductor (L2) is disposed in the power supply path (3), and connected between the first inductor (L1) and the power terminal (14). The first inductor (L1) and the second inductor (L2) are disposed to couple a magnetic field generated at the first inductor (L1) and a magnetic field generated at the second inductor (L2).

The semiconductor module according to this aspect can reduce high-frequency noises.

In a semiconductor module (100, 100A) according to a second aspect based on the first aspect, the first end of the capacitor (C1) is connected to a contact between the first inductor (L1) and the second inductor (L2).

A semiconductor module (100A) according to a third aspect based on the first or second aspect further includes a second semiconductor device (2), a second power supply path (4), and a third inductor (L3). The second semiconductor device (2) is different from a first semiconductor device (1) serving as the semiconductor device (1). The second semiconductor device (2) includes a power terminal (24). The second power supply path (4) is connected between the power terminal (24) of the second semiconductor device (2) and a contact between the first inductor (L1) and the second inductor (L2) at a first power supply path (3) serving as the power supply path (3). The third inductor (L3) is disposed in the second power supply path (4).

The semiconductor module according to this aspect can reduce high-frequency noises leaking from the second power supply path (4) to the second semiconductor device (2).

A semiconductor module (100, 100A) according to a fourth aspect based on the first aspect further includes a module substrate (5). The semiconductor device (1) is disposed in the module substrate (5). The first inductor (L1) and the second inductor (L2) are inner-layer inductors disposed in the module substrate (5). The first inductor (L1) includes a wire portion wound into a spiral shape when viewed in plan in a thickness direction (D1) of the module substrate (5). The second inductor (L2) includes a wire portion wound into a spiral shape when viewed in plan in the thickness direction (D1) of the module substrate (5). The first inductor (L1) and the second inductor (L2) are disposed to couple a magnetic field generated at the first inductor (L1) and a magnetic field generated at the second inductor (L2).

In a semiconductor module (100, 100A) according to a fifth aspect based on the fourth aspect, the first inductor (L1) and the second inductor (L2) are adjacent to each other in the thickness direction (D1) of the module substrate (5).

The semiconductor module according to this aspect can easily couple a magnetic field generated at the first inductor (L1) and a magnetic field generated at the second inductor (L2).

A semiconductor module (100A) according to a sixth aspect based on the third aspect further includes a module substrate (5). The semiconductor device (1) and the second semiconductor device (2) are disposed in the module substrate (5). The first inductor (L1), the second inductor (L2), and the third inductor (L3) are inner-layer inductors disposed in the module substrate (5). The first inductor (L1) includes a wire portion wound into a spiral shape when viewed in plan in a thickness direction (D1) of the module substrate (5). The second inductor (L2) includes a wire portion wound into a spiral shape when viewed in plan in the thickness direction (D1) of the module substrate (5). The third inductor (L3) includes a wire portion wound into a spiral shape when viewed in plan in the thickness direction (D1) of the module substrate (5). The second inductor (L2) and the third inductor (L3) are disposed to couple a magnetic field generated at the second inductor (L2) and a magnetic field generated at the third inductor (L3). The first inductor (L1) and the third inductor (L3) are disposed to cancel out a magnetic field generated at the first inductor (L1) and the magnetic field generated at the third inductor (L3).

The semiconductor module according to this aspect can improve isolation between the first power supply path (3) and the second power supply path (4).

A semiconductor module (100A) according to a seventh aspect is based on the sixth aspect. In the semiconductor module (100A), in the thickness direction (D1) of the module substrate (5), the wire portion of the first inductor (L1) and the wire portion of the second inductor (L2) are adjacent to each other. The wire portion of the second inductor (L2) and the wire portion of the third inductor (L3) are adjacent to each other. The wire portion of the first inductor (L1) and the wire portion of the third inductor (L3) are not adjacent to each other.

The semiconductor module according to this aspect can achieve size reduction.

A semiconductor module (100, 100A) according to an eighth aspect based on any one of the first to third aspects further includes a module substrate (5). The semiconductor device (1) is disposed in the module substrate (5). One of a wire portion of the first inductor (L1) and a wire portion of the second inductor (L2) is a chip inductor (L0) disposed in the module substrate (5). The chip inductor (L0) includes a wound portion (9). A remaining one of the wire portion of the first inductor (L1) and the wire portion of the second inductor (L2) is an inner-layer inductor disposed in the module substrate (5) and having a spiral shape. A winding axis (A1) of the wound portion (9) of the wire portion of the chip inductor (L0) is parallel to a thickness direction (D1) of the module substrate (5). The wire portion of the first inductor (L1) and the wire portion of the second inductor (L2) at least partially overlap when viewed in plan in the thickness direction (D1) of the module substrate (5).

The semiconductor device 1, the second semiconductor device 2, the matching circuits MN1/MN2, and any control logic associated therewith may be implemented as circuitry. The functionality of the elements disclosed herein may be implemented using circuitry or processing circuitry which includes general purpose processors, special purpose processors, integrated circuits, ASICs (“Application Specific Integrated Circuits”), FPGAs (“Field Programmable Gate Arrays”), conventional circuitry and/or combinations thereof which are programmed, using one or more programs stored in one or more memories, or otherwise configured to perform the disclosed functionality. Processors are considered processing circuitry or circuitry as they include transistors and other circuitry therein. The processor may be a programmed processor which executes a program stored in a memory. In the disclosure, the circuitry, units, or means are hardware that carry out or are programmed to perform the recited functionality. The hardware may be any hardware disclosed herein which is programmed or configured to carry out the recited functionality

### REFERENCE SIGNS LIST

1 semiconductor device (first semiconductor device)
11 input terminal (first input terminal)
12 output terminal (first output terminal)
13 grounding terminal (first grounding terminal)
14 power terminal
2 second semiconductor device
21 input terminal (second input terminal)
22 output terminal (second output terminal)
23 grounding terminal (second grounding terminal)
24 power terminal
3 power supply path (first power supply path)
4 second power supply path
5 module substrate
50 main surface
7 direct-current power supply
8 element
9 wound portion
100, 100A semiconductor module
A1 winding axis
L0 chip inductor
L1 first inductor
L2 second inductor
L3 third inductor
C1 capacitor (first capacitor)
C2 second capacitor
MN1 first matching circuit
MN2 second matching circuit
T1 first terminal
T2 second terminal
T3 third terminal

1. A semiconductor module, comprising:
a semiconductor device including a power terminal;
a power supply path connected to the power terminal of the semiconductor device;
a first inductor disposed in the power supply path;
a capacitor having a first end and a second end, the first end being connected to the power supply path, the second end being connected to a ground reference; and
a second inductor disposed in the power supply path, the second inductor being connected between the first inductor and the power terminal,
wherein the first inductor and the second inductor are arranged to magnetically couple a magnetic field generated at the first inductor and a magnetic field generated at the second inductor.

2. The semiconductor module according to claim 1,
wherein the first end of the capacitor is connected to a node between the first inductor and the second inductor.

3. The semiconductor module according to claim 1, further comprising:
a second semiconductor device different from a first semiconductor device serving as the semiconductor device, the second semiconductor device including a power terminal;
a second power supply path connected between the power terminal of the second semiconductor device and a path between the first inductor and the second inductor at a first power supply path serving as the power supply path; and
a third inductor disposed in the second power supply path.

4. The semiconductor module according to claim 1, further comprising:
a module substrate,
wherein the semiconductor device is disposed in the module substrate,
wherein the first inductor and the second inductor are inner-layer inductors disposed in the module substrate,
wherein the first inductor includes a wire portion wound into a spiral shape when viewed in plan in a thickness direction of the module substrate,
wherein the second inductor includes a wire portion wound into a spiral shape when viewed in plan in the thickness direction of the module substrate, and
wherein the first inductor and the second inductor are disposed to couple a magnetic field generated at the first inductor and a magnetic field generated at the second inductor.

5. The semiconductor module according to claim 4,
wherein the first inductor and the second inductor are adjacent to each other in the thickness direction of the module substrate.

6. The semiconductor module according to claim 3, further comprising:
a module substrate,
wherein the first semiconductor device and the second semiconductor device are disposed in the module substrate,
wherein the first inductor, the second inductor, and the third inductor are inner-layer inductors disposed in the module substrate,
wherein the first inductor includes a wire portion wound into a spiral shape when viewed in plan in a thickness direction of the module substrate,
wherein the second inductor includes a wire portion wound into a spiral shape when viewed in plan in the thickness direction of the module substrate,
wherein the third inductor includes a wire portion wound into a spiral shape when viewed in plan in the thickness direction of the module substrate,
wherein the second inductor and the third inductor are disposed to couple a magnetic field generated at the second inductor and a magnetic field generated at the third inductor, and
wherein the first inductor and the third inductor are disposed to cancel out a magnetic field generated at the first inductor and the magnetic field generated at the third inductor.

7. The semiconductor module according to claim 6,
wherein, in the thickness direction of the module substrate,
the wire portion of the first inductor and the wire portion of the second inductor are adjacent to each other,
the wire portion of the second inductor and the wire portion of the third inductor are adjacent to each other, and
the wire portion of the first inductor and the wire portion of the third inductor are not adjacent to each other.

8. The semiconductor module according to claim 1, further comprising:
a module substrate,
wherein the semiconductor device is disposed in the module substrate,
wherein a first one of a wire portion of the first inductor and a wire portion of the second inductor is a chip inductor disposed in the module substrate and including a wound portion,
wherein a second one of the wire portion of the first inductor and the wire portion of the second inductor is an inner-layer inductor disposed in the module substrate and having a spiral shape,
wherein a winding axis of the wound portion of the wire portion of the chip inductor is parallel to a thickness direction of the module substrate, and
wherein the wire portion of the first inductor and the wire portion of the second inductor at least partially overlap when viewed in plan in the thickness direction of the module substrate.

9. The semiconductor module according to claim 1, wherein the first inductor and the second inductor are negatively coupled such that a negative mutual inductance is generated.

10. The semiconductor module according to claim 1, wherein the semiconductor device includes a radio frequency (RF) power amplifier.

11. A semiconductor module, comprising:
a module substrate;
a semiconductor device disposed in the module substrate and including a power terminal;
a power supply path connected to the power terminal;
a first inductor disposed in the power supply path; a capacitor connected between the power supply path and a ground; and
a second inductor disposed in the power supply path between the first inductor and the power terminal; wherein
the first inductor and the second inductor include inner-layer inductors disposed in the module substrate,
the first inductor includes a wire portion wound into a spiral shape when viewed in plan in a thickness direction of the module substrate, and
the second inductor includes a wire portion wound into a spiral shape when viewed in plan in the thickness direction of the module substrate.

12. The semiconductor module according to claim 11,
wherein the first inductor and the second inductor are adjacent to each other in the thickness direction of the module substrate.

13. The semiconductor module according to claim 12, wherein a winding direction of the first inductor is opposite to a winding direction of the second inductor.

14. The semiconductor module according to claim 11, wherein the capacitor includes a chip capacitor mounted on a main surface of the module substrate.

15. The semiconductor module according to claim 11, wherein the first inductor and the second inductor at least partially overlap in the thickness direction of the module substrate.

16. The semiconductor module according to claim 8, wherein the first inductor is connected to the second inductor by a via conductor extending in the thickness direction of the module substrate.

17. A semiconductor module, comprising:
a first semiconductor device including a first power terminal; a
second semiconductor device including a second power terminal;
a first power supply path connected to the first power terminal;
a first inductor and a second inductor disposed in the first power supply path;
a capacitor connected between the first power supply path and a ground reference;
a second power supply path connected between the second power terminal and a node between the first inductor and the second inductor; and
a third inductor disposed in the second power supply path, wherein
the first inductor and the second inductor are magnetically coupled, and
the second inductor and the third inductor are magnetically coupled.

18. The semiconductor module according to claim 17, further comprising:
a module substrate, wherein
the first semiconductor device and the second semiconductor device are disposed in the module substrate,
the first inductor, the second inductor, and the third inductor include inner-layer inductors disposed in the module substrate, and
each of the first, second, and third inductors includes a wire portion wound into a spiral shape when viewed in plan in a thickness direction of the module substrate.

19. The semiconductor module according to claim 17, further comprising a first matching circuit connected to an input of the first semiconductor device and a second matching circuit connected between an output of the first semiconductor device and an input of the second semiconductor device.

20. The semiconductor module according to claim 17, wherein the first, second, and third inductors are arranged in that order in a thickness direction of a module substrate supporting the first and second semiconductor devices.
